(19) United States
(12) Patent Application Publication
(10) Pub. No.: US 2008/0029148 A1
(43) Pub. Date: Feb. 7, 2008

(54) FLOATING SUPPORT STRUCTURE FOR A SOLAR PANEL ARRAY

(76) Inventor: Daniel S. Thompson, San Rafael, CA (US)

Correspondence Address: STAINBROOK & STAINBROOK, LLP, 412 AVIATION BOULEVARD, SUITE H, SANTA ROSA, CA, 95403, US

(21) Appl. No.: 11/861,226

(22) Filed: Sep. 25, 2007

Related U.S. Application Data
(63) Continuation-in-part of application No. 11/264,285, filed on Oct. 31, 2005.
(60) Provisional application No. 60/623,328, filed on Oct. 29, 2004.

(51) Int. Cl. H01L 31/02

(52) U.S. Cl. 136/244

(57) ABSTRACT

A floating support structure for a solar panel array having flotation elements and a support structure disposed above the flotation elements for adjustably and removably mounting at least one solar collector panel. Connectors joining floatation elements form a platform for gangways and catwalks providing access for installation, repair, and maintenance, even when the solar panel array is installed on a body of water.

### CROSS REFERENCE TO RELATED APPLICATIONS

The present application is a continuation-in-part of U.S. Utility patent application Ser. No. 11/264,285, filed 10/31/2005 (Oct. 31, 2005), which claims the benefit of U.S. Provisional Patent Application, Ser. No. 60/623,328, filed 10/29/2004 (Oct. 29, 2004).

### STATEMENT REGARDING FEDERALLY SPONSORED RESEARCH OR DEVELOPMENT

Not applicable.

### REFERENCE TO A MICROFICHE APPENDIX

Not applicable.

### TECHNICAL FIELD

The present invention relates generally to photovoltaic power systems, and more particularly to support structures for solar photovoltaic collector panels, and still more particularly to a modular floating support structure for a solar panel array.

### BACKGROUND INFORMATION AND DISCUSSION OF RELATED ART

With a few exceptions, solar panel support structures are almost invariably adapted for installation of a solar panel on the ground or a rooftop. Notable exceptions include support frameworks for mounting solar panels on vehicles and boats, and more exotic uses may even call for an installation with no support framework, such as with small glue on/screw on thin solar panels for use in extreme environments.

Rooftop solar arrays require the modification of the rooftop structure, can be dangerous and difficult to work on, and provide only a limited footprint. On the other hand, land is increasingly expensive and may be exploited for a number of purposes other than solar array installation. Additionally, the amount of land required for a solar array that generates a significant amount of electrical power can be considerable. Accordingly, because bodies of water comprise two thirds of the surface area of the earth, and because many large areas of water surfaces have no critical uses that cannot be provided for elsewhere, it may be desirable to dedicate large surface areas of water to the collection of solar energy and the conversion of solar energy to electricity.

There is as yet no known art showing suitable flotation elements for installing and deploying a large solar array on a body of water.

### BRIEF SUMMARY OF THE INVENTION

The present invention is a floating support structure for solar collectors. The invention provides for water-mounting of an array of solar panels with no ground mounts, roof mounts, minimal materials and minimal labor in installation. In addition, the invention includes a pre-angled mounting component for tilting the array (herein after referred to as “framework”) at a desired angle for best collection of solar radiation (e.g., 20 degrees). It also provides for transverse angling of the entire array on water, which incorporates posts mounted vertical and separately.

The inventive apparatus comprises a number of lightweight elongate tube elements that can be assembled at the time of manufacture. Alternatively, because the tubular elements are easily stacked and compactly stored, the assembly elements can be transported to an installation site and assembled at the site.

It is therefore an object of the present invention to provide a new and improved modular floating support structure for a solar panel.

It is another object of the present invention to provide a new and improved floating support structure for a solar panel array that may be connected to other like modules to form an array.

A further object or feature of the present invention is a new and improved floating structure for a solar panel array that permits solar panels to be tilted for optimum solar energy collection while afloat.

An even further object of the present invention is to provide a novel floating structure for a solar panel array that is lightweight and easily transported to and assembled at or near an installation site.

There has thus been broadly outlined the more important features of the invention in order that the detailed description that follows may be better understood, and in order that the present contribution to the art may be better appreciated. Additional objects, advantages and novel features of the invention will be set forth in part in the description as follows, and in part will become apparent to those skilled in the art upon examination of the following. Furthermore, such objects, advantages and features may be learned by practice of the invention, or may be realized and attained by means of the instrumentalities and combinations particularly pointed out in the appended claims.

Still other objects and advantages of the present invention will become readily apparent to those skilled in this art from the following detailed description, which shows and describes only the preferred embodiments of the invention, simply by way of illustration of the best mode now contemplated of carrying out the invention. As will be realized, the invention is capable of modification in various obvious respects without departing from the invention. Accordingly, the drawings and description of the preferred embodiment are to be regarded as illustrative in nature, and not as restrictive.

### BRIEF DESCRIPTION OF THE SEVERAL VIEWS OF THE DRAWINGS

The invention will be better understood and objects other than those set forth above will become apparent when consideration is given to the following detailed description thereof. Such description makes reference to the annexed drawings wherein:

FIG. 1 is a perspective view of the modular floating support structure of the present invention, shown supporting two solar panels;

FIG. 2is a front view in elevation thereof;

FIG. 3 is a rear view in elevation thereof;

FIG. 4 is a side view in elevation thereof;

FIG. 5is a side view in elevation of a plurality of the modular floating support structures showing how such structures may be connected and deployed in a floating solar panel array;

FIG. 5A is a perspective view showing a bar with carabineers disposed at its ends as used to connect adjacent modules at their respective sides;

FIG. 6 is a top view showing a plurality of the inventive modular support structures connected in an array;

FIG. 7 is a side view in elevation of a second preferred embodiment of the present invention, showing an individual floatation element and a solar panel mounted thereto;

FIG. 7A is a rear view thereof;

FIG. 7B is a side view in elevation of a solar panel array mounted on a plurality of the floatation and support elements shown in FIGS. 7 and 7A;

FIG. 8 is a top plan view thereof, the floatation elements being shown with phantom lines;

FIG. 9 is a side view in elevation of the floatation element of the second preferred embodiment showing the structural components in phantom;

FIG. 10 is an end view in elevation of the exterior interior portion of the end cap for the floatation element of the second preferred embodiment, shown along line 10-10 of FIG. 11;

FIG. 11 is a cross-sectional side view in elevation showing the end cap, exterior and interior tubes, and mounting apertures of the floatation element, the view taken along section line 11-11 of FIG. 10;

FIG. 12 is an end view in elevation of the interior side of the floatation element end cap viewed from line 12-12 of FIG. 13;

FIG. 13 is a cross-sectional side view in elevation of the end cap and tube elements taken along section line 13-13 of FIG. 12;

FIG. 14 is an upper left front perspective view showing a third preferred embodiment of the modular floating support structure of the present invention, shown supporting an array of solar panels;

FIG. 15 is an upper left perspective of the modular floating support structure and solar panels as shown in FIG. 14;

FIG. 16 is a top plan view of the inventive apparatus supporting a large array of solar panels;

FIG. 17A is a cross-sectional side view in elevation of the inventive apparatus taken along section line 17A-17A of FIG. 16;

FIG. 17B is a cross-sectional side view in elevation of the inventive apparatus taken along section line 17B-17B of FIG. 16;

FIG. 18 is an upper front left perspective view showing detail of the terminal end of the lateral gangway joining elements of the modular floating support structure of the present invention, taken along detail line 18 of FIG. 14;

FIG. 19 is an upper rear left perspective view of the other terminal end of the lateral gangway, taken along detail line 19 of FIG. 15;

FIG. 20 is an upper perspective view of an alternative floatation element for the inventive apparatus;

FIG. 21 is an exploded view showing the floatation element of FIG. 20;

FIG. 22 is a cross-sectional end view in elevation taken along section line 22-22 of FIG. 20;

FIG. 23 is a cross-sectional side view in elevation showing a fourth preferred embodiment of the floatation element of the present invention; and

FIG. 23 is a cross-sectional side view in elevation of a fifth preferred embodiment of the floatation element.

### DETAILED DESCRIPTION OF THE INVENTION

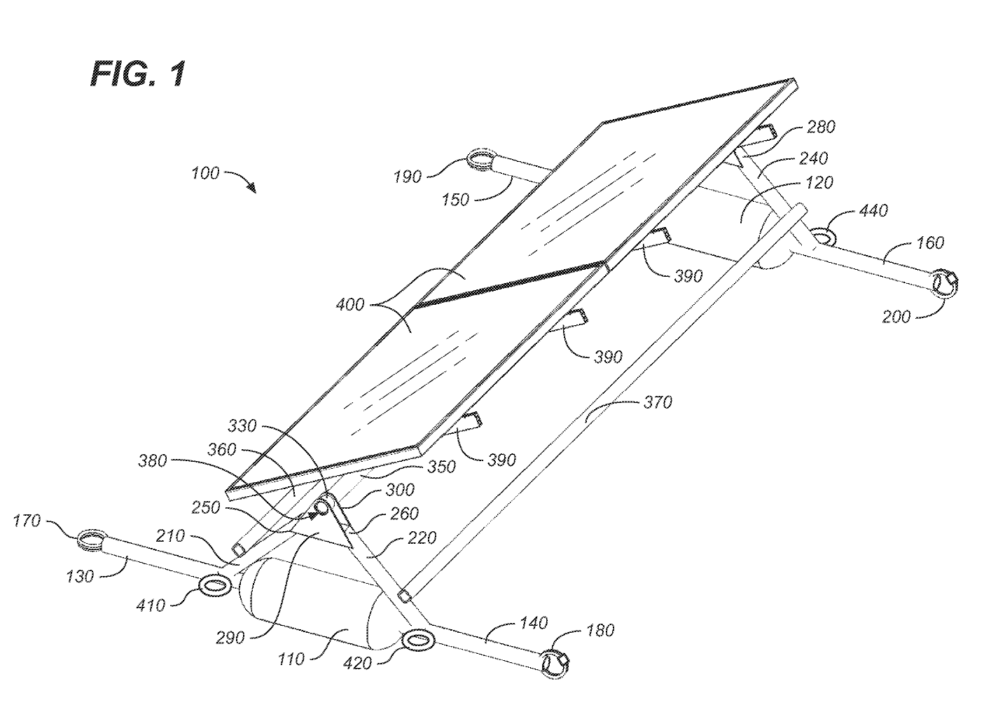

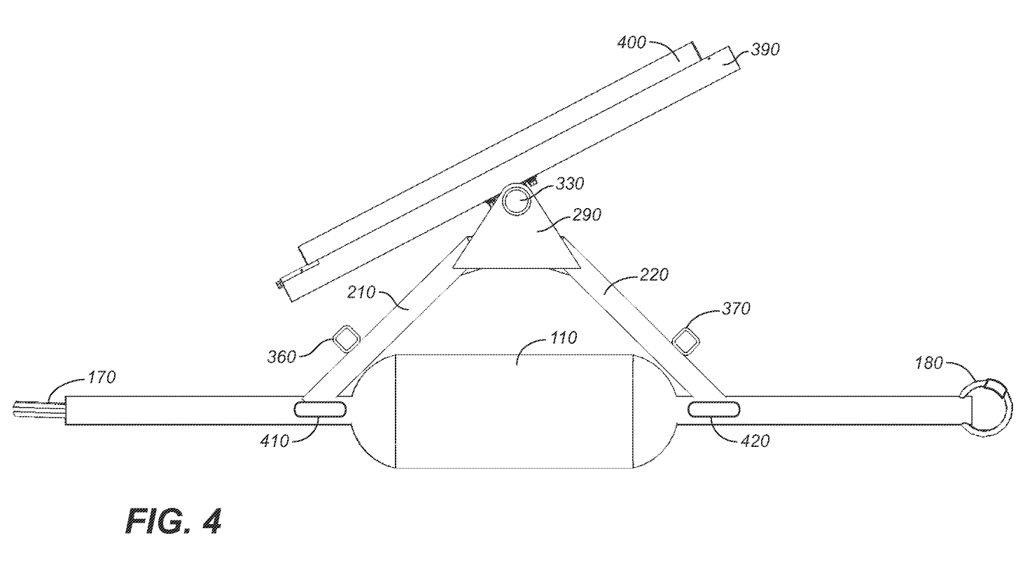

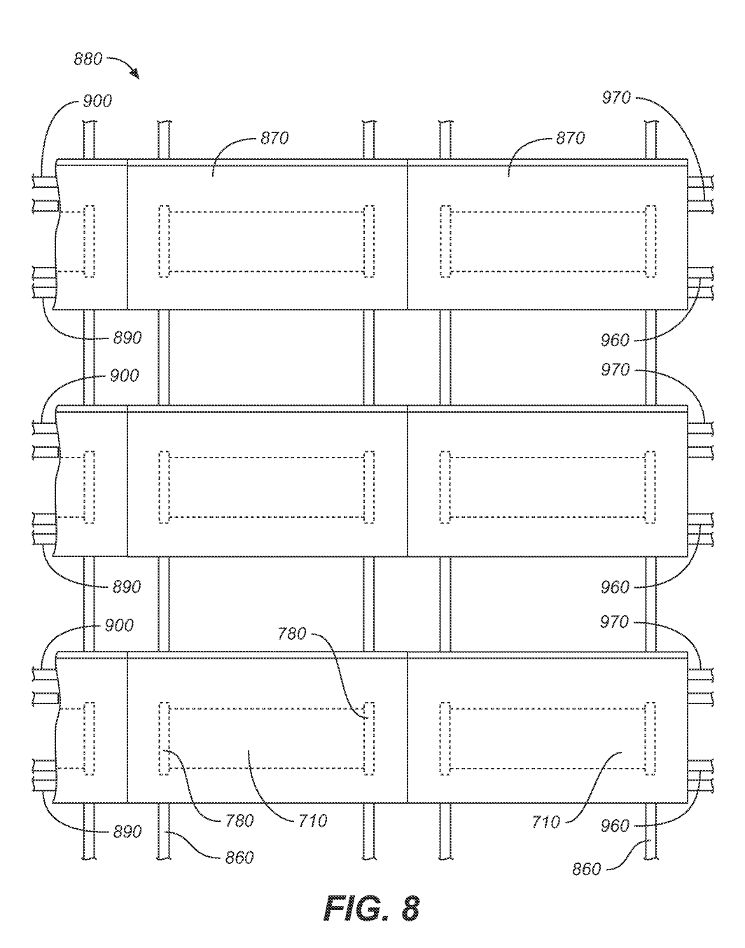

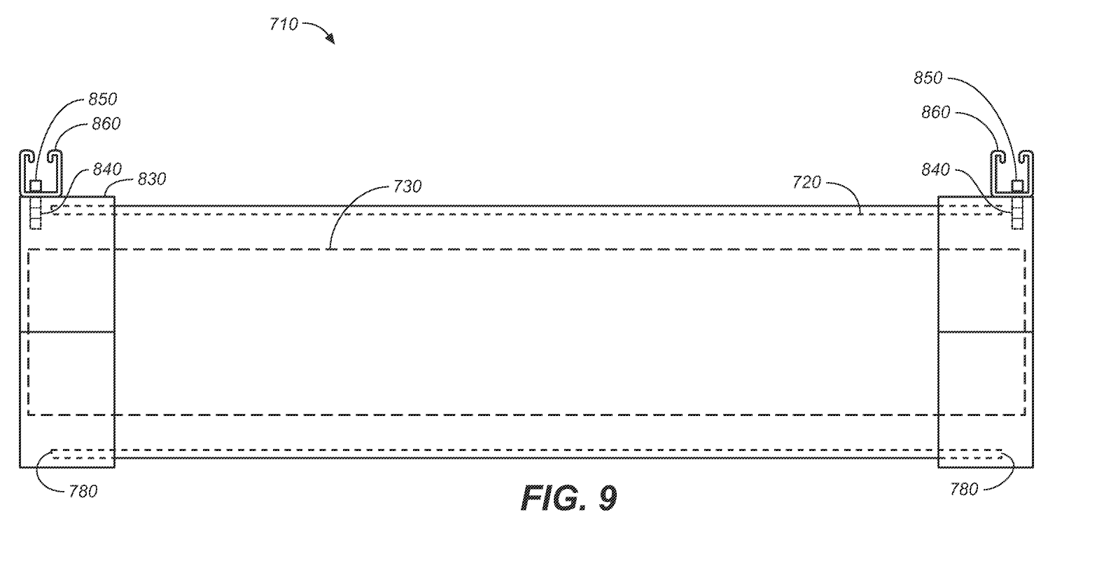

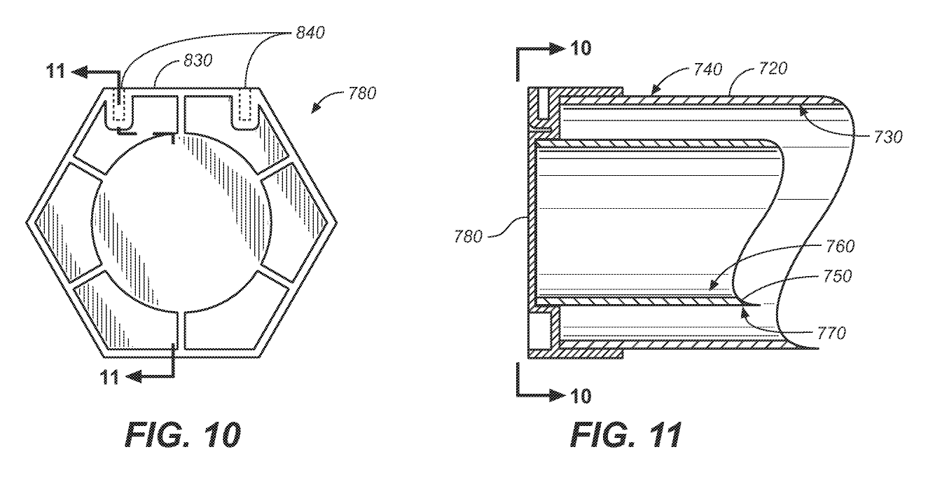

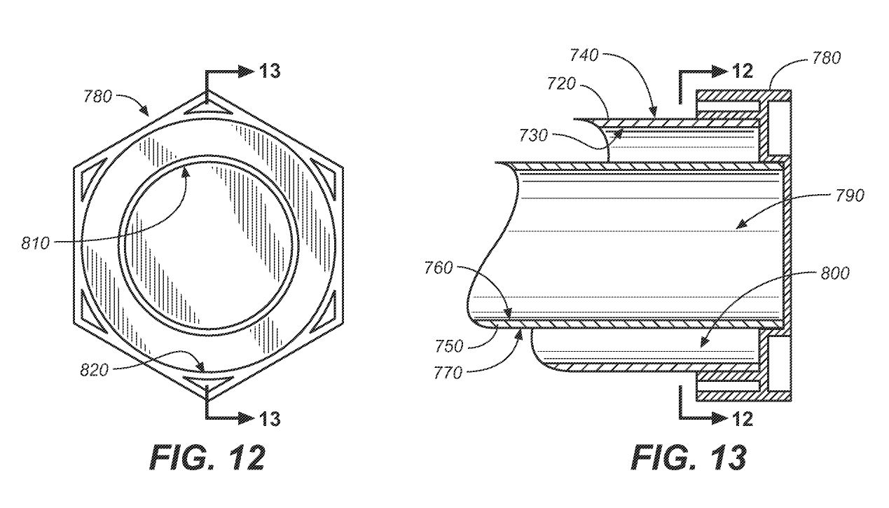

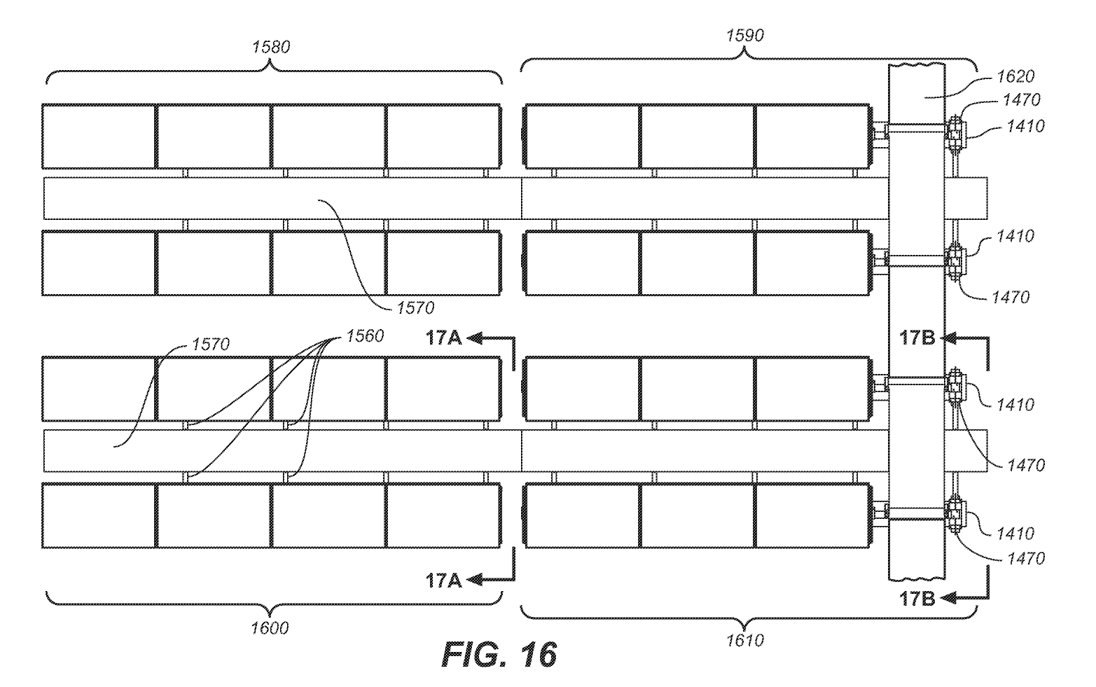

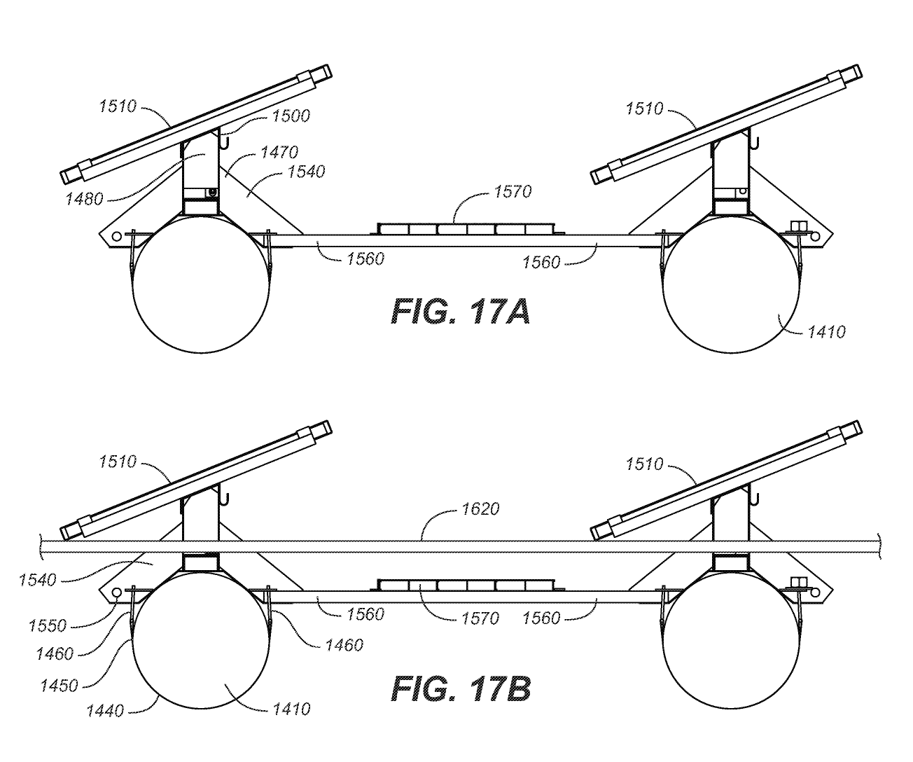

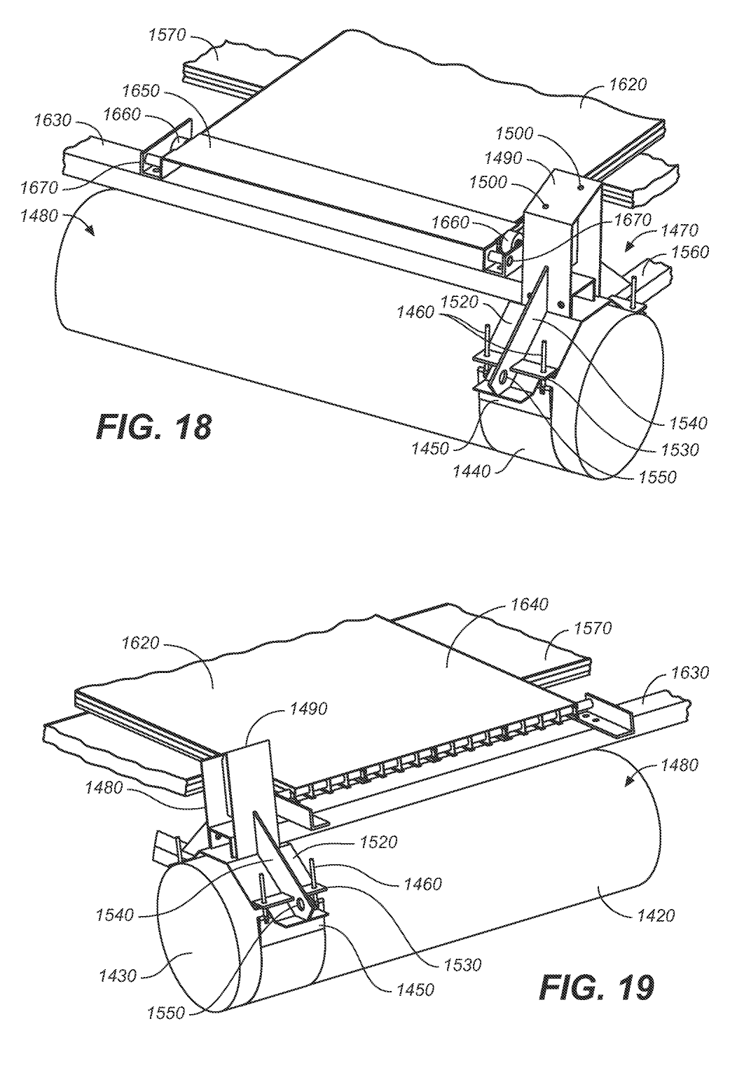

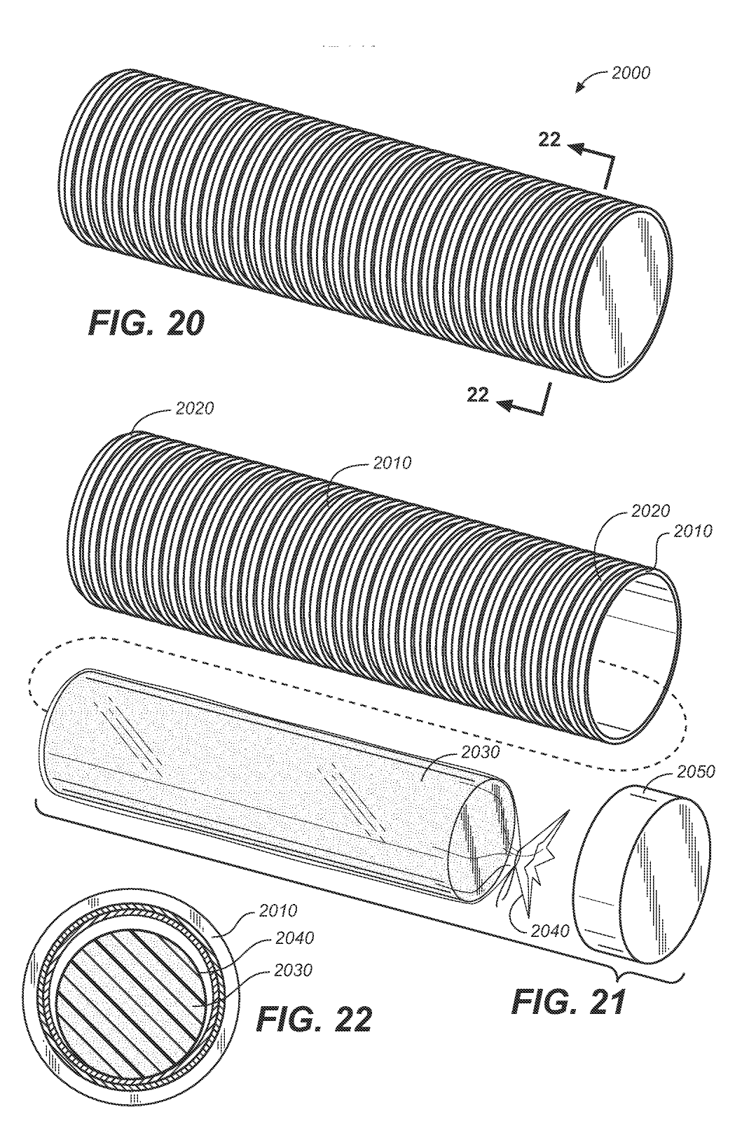

Referring to FIGS. 1 through 23, wherein like reference numerals refer to like components in the various views, there is illustrated therein a new and improved modular floating support structure for a solar panel array, the first preferred embodiment of which is generally denominated 100 herein.

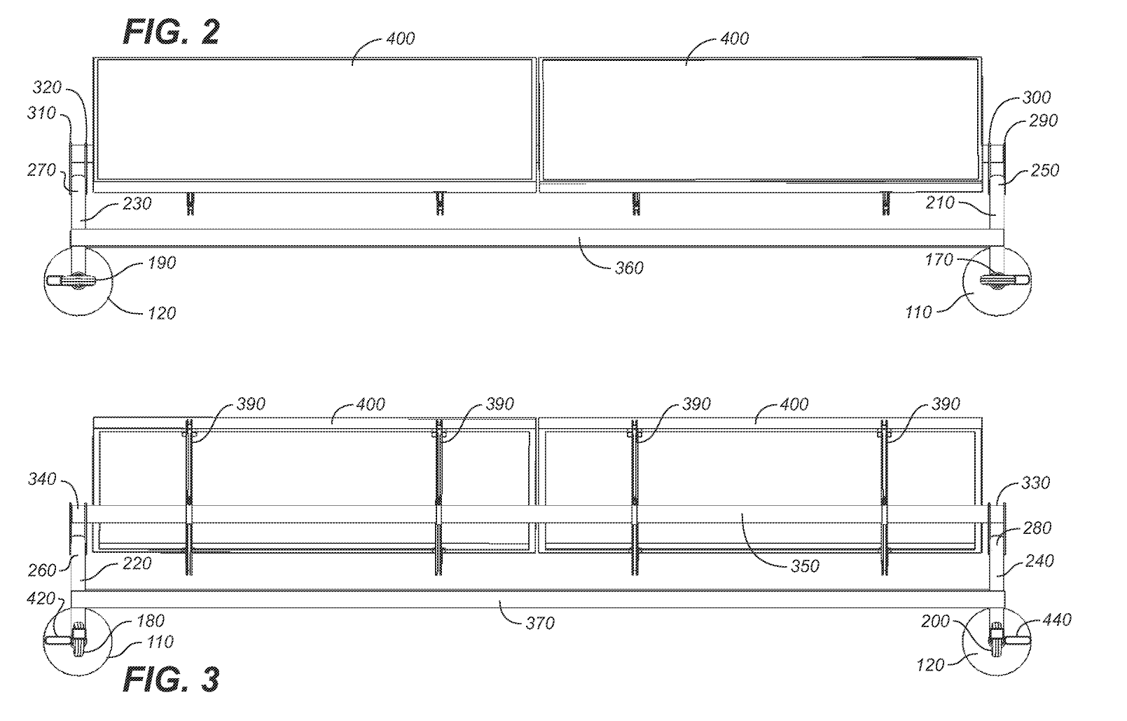

FIG. 1 is a perspective view of the first preferred embodiment of the modular support structure, while FIGS. 2, 3, and 4 are, respectively, front, back, and side elevation views of the module of FIG. 1. Collectively, these views show that this basic modular component of a floating array comprises first and second elongate flotation elements 110, 120, preferably substantially cylindrical pontoons, each having connector tubes 130, 140, and 150, 160, extending longitudinally from each end of the pontoons. Preferably the connector tubes are round in cross section, and their respective distal ends include front and rear connection means, preferably connector rings, 170, 190, and 180, 200, respectively. The front connector rings 170, 190 are disposed generally perpendicular to the rear connector rings 180, 200, and either the front or rear connector rings or both are provided with a hinge element that allows the rings to capture rings in an adjacent module, in the manner of a tubular carabineer. Effectively, then, one set of connector rings comprises rigid connector rings, while the complementary set of connector rings comprises carabineers that attach to the rigid connector rings. As with carabineers, it is well known to provide locking means to prevent the hinge element in the carabineer from inadvertently opening. Such structures considered obvious design choices and are contemplated within the scope of the present invention.

Straddling the ends of each flotation element are angled upright supports, 210, 220, and 230, 240, glued, welded, bolted, or otherwise affixed at their lower ends to the connector tubes extending longitudinally from the flotation element, or to the flotation elements themselves, and which angle inwardly toward one another to join or substantially join at their respective upper ends, 250, 260, and 270, 280. The angled uprights are preferably fabricated from square tubing. The manufacturing means may be adapted to the anticipated installation, as welding or gluing may provide a sturdier structure with greater durability, but assembly with nuts and bolts may allow for easy transportation for assembly at an installation site.

Spaced apart parallel plates 290/300, and 310/320, may be glued, welded, bolted, or otherwise rigidly affixed to the opposite sides of the uprights at or near the junction of the upper ends of the angled uprights to provide increased structural integrity. Additionally, the plates may be provided with holes in which to journal the ends 330, 340 of a rotatable panel frame mounting tube 350. Two or more additional transverse tubes 360, 370, may be disposed between, and connected to, the angled uprights, so as to make a generally rigid framework structure. Adjustment/locking means 380 may be provided to permit selective release, rotation, and re-locking of the mounting tube. A number of suitable devices can be provided, including hole and nipple assemblies, pawl and ratchet, locking collar and ring, and the like. The drawings show a pawl and ratchet assembly as an illustrative mechanism.

The rotatable panel frame mounting tube can be provided with a plurality of support rails 390 on which to fasten and secure one or more solar photovoltaic panels 400.

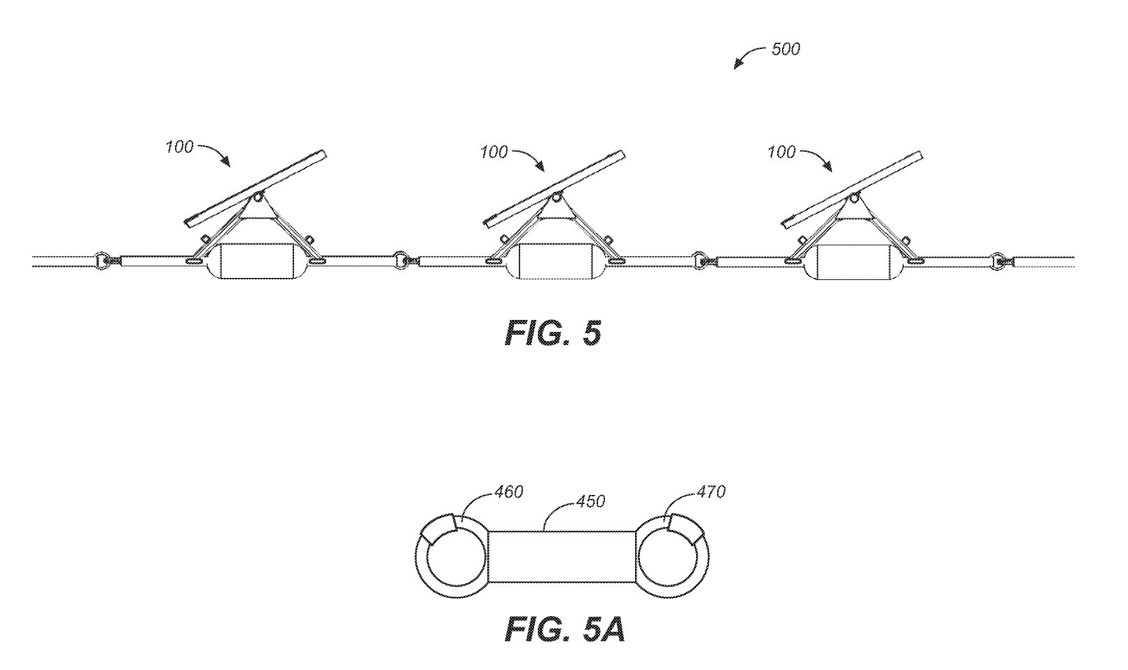

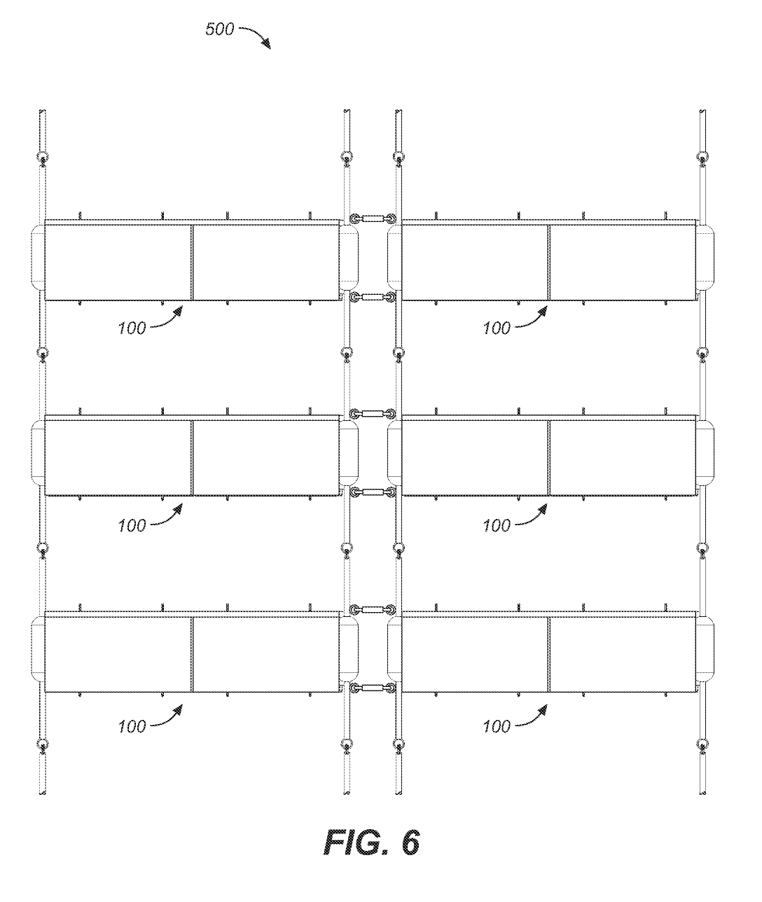

The module framework may also be provided with side connector rings 410, 420, 430, 440, disposed along each of the sides of the support structure. While only one side connector ring need be provided for each side of the support structure, and may be positioned anywhere along the length of the flotation element or connector tubes, it is preferable to have two side connector rings, one each extending outwardly from a each front and rear connector tube. Referring now to FIG. 5A, side connector bars 450, having hinged carabineers connector rings 460, 470 at each end may then be provided as means for joining the sides of adjacent support modules in a floating solar panel array 500 (see FIGS. 5 and 6). As an alternative, a side connector bar may be provided for installation between the front or rear connector ring of an adjoining support structure, so that no additional rings need be provided to ensure that the spacing between floating modules is fixed.

FIGS. 5 and 6 show the modules of FIGS. 1-4 connected with the above-described connector rings and side connector bars to form a floating solar panel array 500. The support modules are preferably spaced in accordance with ambient wave conditions of the body of water in which the installation will be deployed. Thus, the sizing and weight distribution of each module, and the spacing of modules relative to one another, can be tailored to minimize roll, pitch, yaw, heave, surge and sway under the wave conditions most likely to be encountered in the particular environment of use.

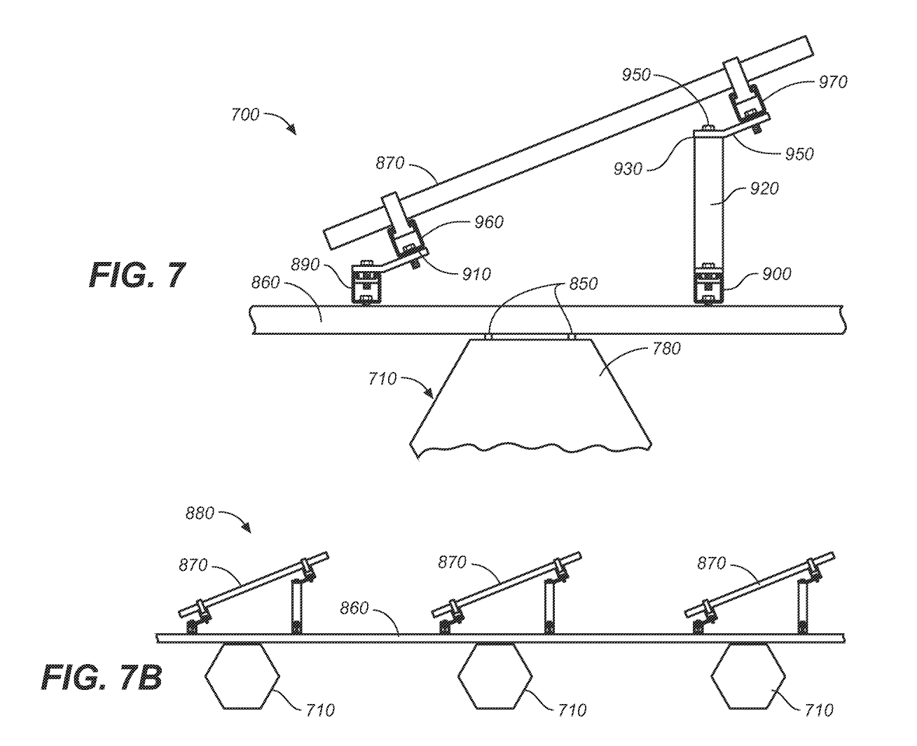

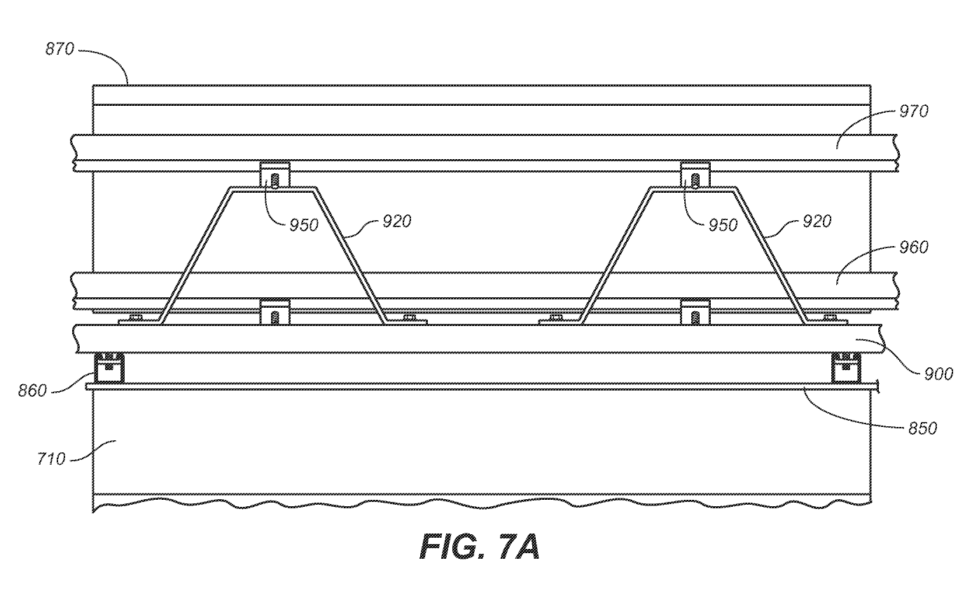

FIGS. 7-13 show a second preferred embodiment 700 of the modular floating support structure for a solar panel array of the present invention. In this alternative embodiment, the floatation elements 710 comprise an outer tube 720 having an interior wall 730 and an exterior surface 740, an inner tube 750 having an interior wall 760 and an exterior surface 770 spaced apart from the interior wall of the outer tube, and polygonal end caps 780 welded to the ends of the outer and inner tubes so as to create a watertight and airtight seal over first and second air chambers 790, 800.

The end caps 780 are preferably polygonal when viewed on end (see FIG. 7), and are conformed on an interior surface with an inner socket 810 which tightly fits over, captures, and retains an end of the inner tube 750 when welded, and an outer socket 820 which tightly fits over, captures, and retains an end of the outer tube 720 when welded. The top side 830 of the end caps essentially comprise a mounting platform which include apertures 840, preferably threaded, for accepting mounting bolts 850 to be employed in fastening the solar panel mounting structures.

The foundation of the mounting structures includes front and back lowermost structural channel 860 preferably aluminum extrusions, which are mounted on the top side of the floatation elements with mounting bolts 850 and span transversely across the top sides of the floatation elements to join each adjacent pair into a structural foundation for one or more solar panels 870 in a solar panel array 880.

The second elements in the mounting structure include front and rear longitudinal structural channels 890, 900, which are removably mounted onto the lowermost structural channels 860 in a generally perpendicular orientation. A front foot 910, preferably bent solid bar, is removably mounted on the front longitudinal structural channel 890. A back modified queen post truss 920, with or without interior vertical supports, and also preferably bent solid bar, is removably mounted on the rear longitudinal structural channel 900. The truss includes a horizontal keystone portion 930 having apertures (not shown) for passing bolts 940 to removably mount a rear foot 950, also preferably bent sold bar. Front and rear panel rails 960, 970, attached to and disposed on the underside of each of the solar panels, are attached to the front foot and rear foot, respectively.

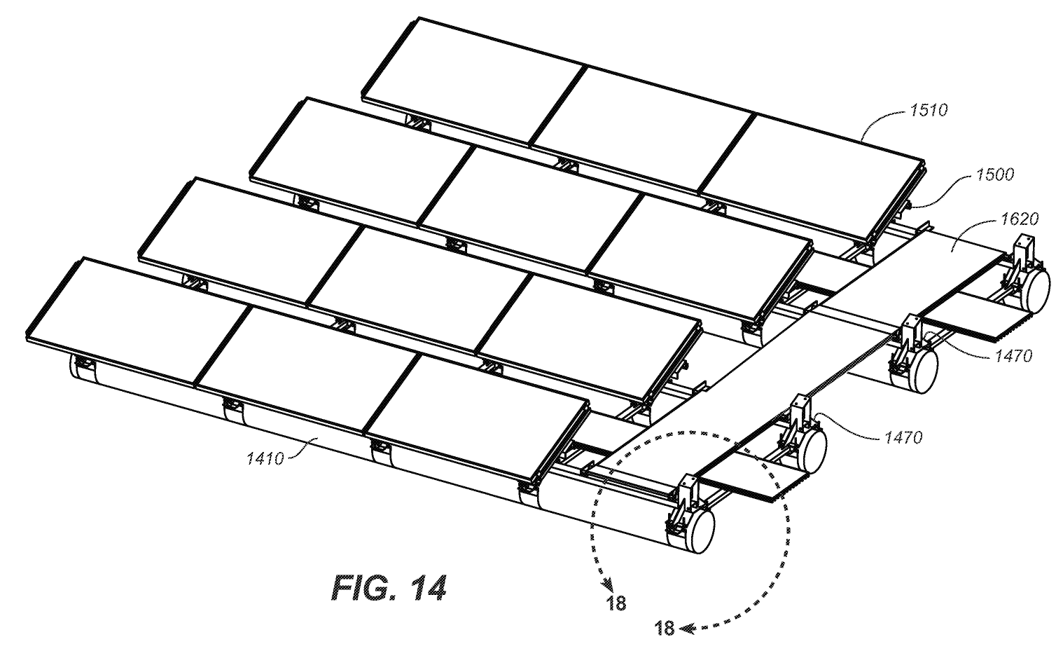

FIGS. 14-19 show a third preferred embodiment 1400 of the modular floating support structure for a solar panel array of the present invention. In this embodiment each of the floatation elements 1410 comprises a single substantially cylindrical tube or pipe 1420 covered with a welded cap 1430 at each end to form a watertight and airtight seal, as is well known in the art. The tubes are preferably fabricated from readily available PVC, HDPE, ABS, CPVC tubing material, though numerous other watertight materials would be perfectly suitable.

Mounting elements are disposed along the length of the floatation elements and proximate the ends. These structures include a slightly flexible metal band 1440 having ends 1450 with bolts 1460 extending therefrom. A mounting bracket 1470 is provided for placement over the top portion 1480 of the cylindrical pipe 1420. The mounting bracket 1470 includes a mounting post 1480 having an angled top 1490 with apertures for passing mounting bolts on which to connect panel rails 1500 disposed on the underside of solar panels 1510. The mounting brackets further include downwardly angling shoulders 1520 each having a horizontally extending tab 1530 with apertures for passing the bolts 1460 on the ends of band 1440. When bolts 1460 are tightened onto tabs 1530, the band and mounting bracket form a clamp over the cylindrical floatation element. The shoulders 1520 of the mounting bracket each also include an integral or welded reinforcement bar 1540 having an aperture 1550 for passing a fastener to join a connector bar 1560 between mounting brackets. The connector bars may be structural channel, solid bars, round or rectangular tubes, or other suitably strong elongate connector.

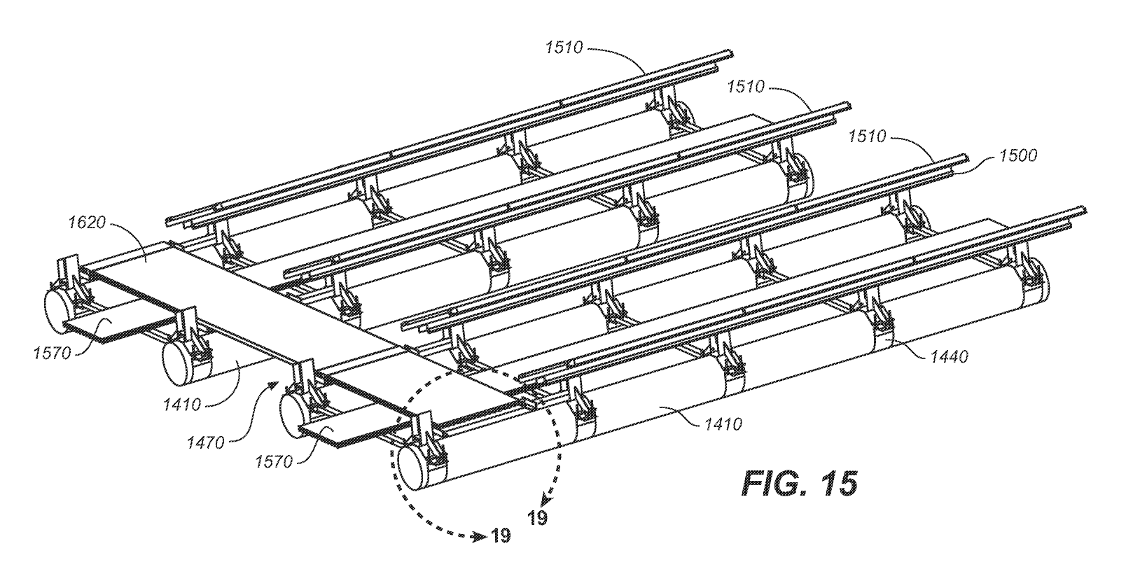

In the above-described and illustrated configuration, the floatation elements, mounting brackets, and connector bars provide a platform for mounting axially disposed gangways 1570, which are placed over the connector bars and provide access to the panels disposed along the length of the floatation elements, even when the apparatus is floating in deep water. Referring now to FIG. 15, it is seen that these elements combine to form discrete modular systems 1580, 1590, 1600, 1610 of the floating apparatus of the present invention. The gangways maybe employed as connectors and when joined end-to-end with another gangway connect adjacent floating modules.

The third preferred embodiment of the inventive floating support structure for a solar panel array also includes a catwalk 1620 disposed over a plurality of floatation elements proximate their respective ends, or between any set of mounting brackets anywhere along the length of the floatation elements where solar panels are not mounted. The catwalk is disposed over mounting bars 1630, preferably extruded aluminum structural channel or steel channel, which extend between mounting brackets 1470. At a first end 1640 the catwalk is firmly attached to a mounting bar. A second end 1650 includes casters 1660 having a small amount of travel in a channel 1670 attached to a mounting bar. This provides some accommodation to movements caused by surface waves on the water. Either the catwalk or any one of the gangways may be joined to a dock to provide access from land to the floating array.

FIGS. 20-22 show a fourth alternative embodiment 2000 of the floatation element of the present invention. In this embodiment, the pontoon comprises doubled walled corrugated pipe having a channel or slot 2010 in each end 2020. A cylinder of foam 2030 covered by a watertight bag 2040 is inserted into the pipe and a cap 2050 placed on the end to form a watertight seal. Mounting apparatus described in connection with the third preferred embodiment may be employed for supporting a solar panel array.

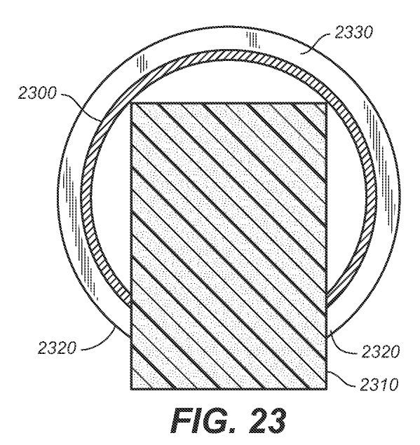

FIG. 23 shows a fifth preferred embodiment of the floatation element. In this embodiment, pipe 2300 is cut along its length to provide an axial opening into which a foam insert 2310 is wedged and captured by resilient ends 2320. Again, mounting apparatus as described in connection with the third preferred embodiment may be employed for supporting a solar panel array. Alternatively, mounting apparatus may be fastened (e.g., by bolts) directly to the upper portion 2330 of the cut pipe.

As will be appreciated by those with skill in the art, a number of suitable materials may be employed for the tubing and flotation elements of the support structure of the present invention for either of the preferred embodiments, including fibre glass, ABS, HDPE, PVC, CPVC, and the like, as well as composite materials, metals and metal alloys, and so forth. The various components need not be fabricated from the same material, and some combination of plastic, composite, and/or metal may be preferable.

The flotation element used in the present invention—i.e., the pontoon—is preferably sealed and may be left either with an unfilled void or it may be filled with polyethylene foam, polystyrene foam, or the like. FIGS. 13-15 show a possible floatation element configuration suitable for use in the present invention. This includes a corrugated cylindrical pipe, a foam insert having a watertight sealed plastic cover bag, and a cap at each end.

The above disclosure is sufficient to enable one of ordinary skill in the art to practice the invention, and provides the best mode of practicing the invention presently contemplated by the inventor. While there is provided herein a full and complete disclosure of the preferred embodiments of this invention, it is not desired to limit the invention to the exact construction, dimensional relationships, and operation shown and described. Various modifications, alternative constructions, changes and equivalents will readily occur to those skilled in the art and may be employed, as suitable, without departing from the true spirit and scope of the invention. Such changes might involve alternative materials, components, structural arrangements, sizes, shapes, forms, functions, operational features or the like.

Therefore, the above description and illustrations should not be construed as limiting the scope of the invention, which is defined by the appended claims.

What is claimed as invention is:

1. A floating support structure for a solar panel array, comprising:
a least two elongate floatation elements; and
mounting structure providing an elevated support for solar panels, said mounting structure removably attached to said floatation elements and adapted for removable connection to a plurality of solar panels.

2. The apparatus of claim 1, wherein said floatation elements include an outer tube having an interior wall and an exterior surface, an inner tube having an interior wall and an exterior surface spaced apart from said interior wall of said outer tube, and polygonal end caps welded to the ends of said outer and inner tubes so as to create a watertight and airtight seal over first and second air chambers.

3. The apparatus of claim 2, wherein said end caps are polygonal and having an interior surface with an inner socket which tightly fits over, captures, and retains an end of said inner tube, an outer socket which tightly fits over, captures, and retains an end of said outer tube, and further having a top side adapted for mounting support elements for supporting the solar panel array.

4. The apparatus of claim 3, wherein said end cap top side includes apertures for accepting mounting bolts.

5. The apparatus of claim 3, further including front and back lowermost structural channels removably mounted to said top side of said end caps and spanning transversely across said floatation elements to join said floatation elements into a structural foundation for one or more solar panels.

6. The apparatus of claim 5, further including front and rear longitudinal structural channels removably mounted onto said lowermost structural channels in a generally perpendicular orientation.

7. The apparatus of claim 6, further including a front foot removably mounted on said front longitudinal structural channel, and a rear vertical support removably mounted on said rear longitudinal structural channel, each having apertures for passing fasteners for removably attaching solar panel rails.

8. The apparatus of claim 7, wherein said rear vertical support comprises a modified queen post truss having a horizontal keystone portion with apertures for passing fasteners to removably mount a rear foot interposed between said queen post truss and said solar panel rail.

9. The apparatus of claim 1, wherein said floatation elements each comprise a single tube having caps welded on its ends to form a watertight and airtight seal.

10. The apparatus of claim 9, wherein said mounting structure includes a plurality of spaced apart metal bands disposed generally on the underside of said tubes, and corresponding mounting brackets, one each connected to one of said metal bands, said mounting bracket having a mounting post for connection to rails disposed on the underside of solar panels,

11. The apparatus of claim 10, wherein said mounting brackets further include downwardly angling shoulders each having connection means for attaching a connector bar between mounting brackets, and one or more connector bars connecting mounting brackets on adjacent floatation elements.

12. The apparatus of claim 11, further including one or more axially disposed gangways placed over and connected to at least one connector bar.

13. The apparatus of claim 11, further including at least one catwalk disposed over a plurality of floatation elements.

14. The apparatus of claim 13, further including at least one mounting bar disposed between said two mounting brackets, and wherein said catwalk is connected to said at least one mounting bar.

15. The apparatus of claim 14, including at least two mounting bars, caster channels affixed to one of said mounting bars, and wherein said catwalk has a first end attached to a mounting bar, and a second end having casters having a small amount of travel in said caster channels.

16. The apparatus of claim 1, wherein said floatation element comprises a corrugated pipe, a foam insert disposed inside said pipe, and caps disposed over each end of said pipe.

17. The apparatus of claim 16, wherein said foam insert is contained in a watertight bag.

18. The apparatus of claim 1, wherein said floatation elements comprises a double-walled corrugated pipe having a slot at each end, a foam insert disposed inside said pipe, and caps inserted in said slots in each end of said pipe.

19. The apparatus of claim 1, wherein said floatation element comprises a pipe axially cut along its length so as to provide resilient ends that can be urged apart to create an axial opening, a foam insert wedged into the axial opening in said pipe and captured by said resilient ends.

20. The apparatus of claim 19, wherein said mounting structure is disposed on top of said floatation elements.
